(19) United States
(12) Patent Application Publication
(10) Pub. No.: US 2024/0055523 A1
(43) Pub. Date: Feb. 15, 2024

(54) THICK GATE OXIDE TRANSISTOR DEVICE AND METHOD

(71) Applicant: Micron Technology, Inc., Boise, ID (US)

(72) Inventors: Bingwu Liu, Meridian, ID (US); Shivani Srivastava, Boise, ID (US); Dan Mihai Mocuta, Boise, ID (US)

(21) Appl. No.: 17/883,736

(22) Filed: Aug. 9, 2022

(51) Int. Cl. H01L 29/78; H01L 27/108; H01L 29/66; H01L 29/08; H01L 21/8234

(52) U.S. Cl. CPC H01L 29/7851; H01L 27/10826; H01L 29/66795; H01L 29/0847; H01L 27/10897; H01L 29/66545; H01L 21/823431

(57) ABSTRACT

Electronic devices and methods are disclosed, including transistors with thick gate dielectric layers. Selected devices and methods shown include multiple layer gate dielectrics. Selected devices and methods shown include a gate dielectric with a first layer having a first width, and a second layer over the first layer, wherein the second layer has a second width smaller than the first width.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface).

The present description relates generally to example structures and methods for improved electrical properties in transistor channels.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a memory device in accordance with some example embodiments.

FIG. 2A illustrates a top view of a FinFET transistor in accordance with some example embodiments.

FIG. 2B illustrates cross section view of the FinFET transistor from FIG. 2A in accordance with some example embodiments.

FIG. 2C illustrates another cross section view of the FinFET transistor from FIG. 2A in accordance with some example embodiments.

FIG. 3A illustrates a cross section view of a manufacturing stage of a FinFET transistor in accordance with some example embodiments.

FIG. 3B illustrates a cross section view of another manufacturing stage of a FinFET transistor in accordance with some example embodiments.

FIG. 4A illustrates a cross section view of another manufacturing stage of a FinFET transistor in accordance with some example embodiments.

FIG. 4B illustrates a cross section view of another manufacturing stage of a FinFET transistor in accordance with some example embodiments.

FIG. 5A illustrates a cross section view of another manufacturing stage of a FinFET transistor in accordance with some example embodiments.

FIG. 5B illustrates a cross section view of another manufacturing stage of a FinFET transistor in accordance with some example embodiments.

FIG. 6 illustrates an example method flow diagram in accordance with other example embodiments.

FIG. 7 illustrates an example block diagram of an information handling system in accordance with some example embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

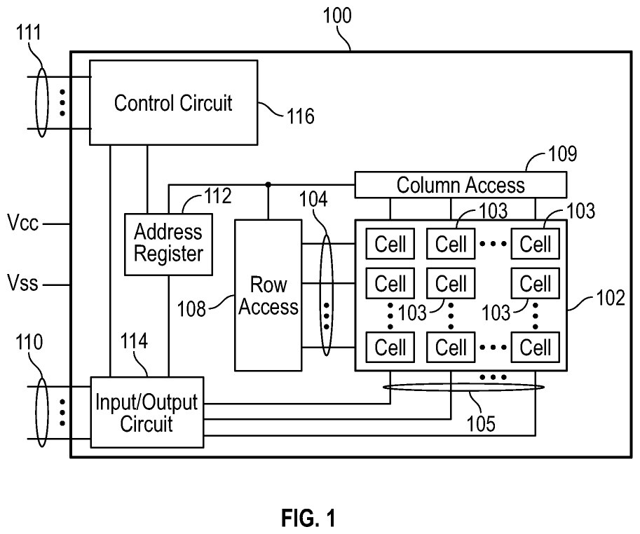

FIG. 1 shows a block diagram of an apparatus in the form of a memory device 100, according to an embodiment of the invention. Memory device 100 can include a memory array 102 having memory cells 103 that can be arranged in rows and columns along with lines (e.g., access lines) 104 and lines (e.g., data lines) 105. Memory cells 103 may include FinFET transistors and utilize methods as described in more detail in subsequent Figures. Memory device 100 can use lines 104 to access memory cells 103 and lines 105 to exchange information with memory cells 103.

Row access 108 and column access 109 circuitry can respond to an address register 112 to access memory cells 103 based on row address and column address signals on lines 110, 111, or both. A data input/output circuit 114 can be configured to exchange information between memory cells 103 and lines 110. Lines 110 and 111 can include nodes within memory device 100 or pins (or solder balls) on a package where memory device 100 can reside.

A control circuit 116 can control operations of memory device 100 based on signals present on lines 110 and 111. A device (e.g., a processor or a memory controller) external to memory device 100 can send different commands (e.g., read, write, or erase commands) to memory device 100 using different combinations of signals on lines 110, 111, or both.

Memory device 100 can respond to commands to perform memory operations on memory cells 103, such as performing a read operation to read information from memory cells 103 or performing a write (e.g., programming) operation to store (e.g., program) information into memory cells 103. Memory device 100 can also perform an erase operation to clear information from some or all of memory cells 103.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or an alternating-current to direct-current (AC-DC) converter circuitry.

Each of memory cells 103 can be programmed to store information representing a value of a fraction of a bit, a value of a single bit, or a value of multiple bits such as two, three, four, or another number of bits. For example, each of memory cells 103 can be programmed to store information representing a binary value “0” or “1” of a single bit. The single bit per cell is sometimes called a single level cell. In another example, each of memory cells 103 can be programmed to store information representing a value for multiple bits, such as one of four possible values “00,” “01,” “10,” and “11” of two bits, one of eight possible values “000,” “001,” “010,” “011,” “100,” “101,” “110,” and “111” of three bits, or one of other values of another number of multiple bits. A cell that has the ability to store multiple bits is sometimes called a multi-level cell (or multi-state cell).

Memory device 100 can include a non-volatile memory device, and memory cells 103 can include non-volatile memory cells, such that memory cells 103 can retain information stored thereon when power (e.g., Vcc, Vss, or both) is disconnected from memory device 100. For example, memory device 100 can be a flash memory device, such as a NAND flash or a NOR flash memory device, or another kind of memory device, such as a variable resistance memory device (e.g., a phase change or resistive RAM device).

Memory device 100 can include a memory device where memory cells 103 can be physically located in multiple levels on the same device, such that some of memory cells 103 can be stacked over some other memory cells 103 in multiple levels over a substrate (e.g., a semiconductor substrate) of memory device 100.

One of ordinary skill in the art will recognize that memory device 100 may include other elements, several of which are not shown in FIG. 1, so as not to obscure the example embodiments described herein.

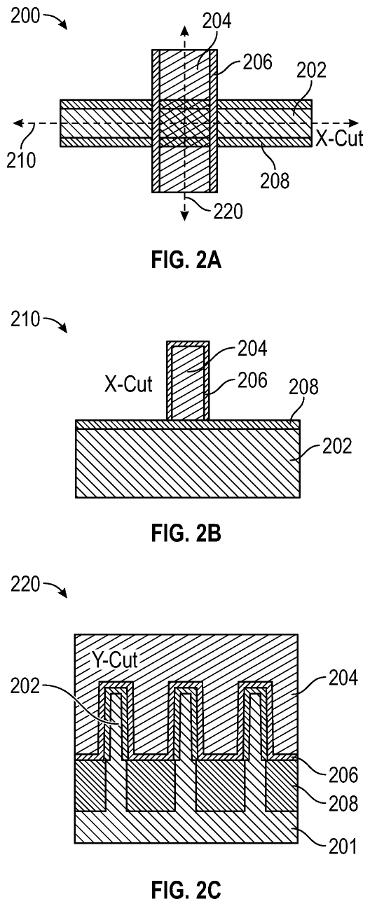

FIG. 2A shows a top view of a FinFET transistor 200 according to one example. A semiconductor fin 202 is shown. A dummy gate 204 is patterned over the fin 202 and a nitride layer 206 is formed in a conformal layer over the dummy gate 204. FIG. 2A further shows a gate dielectric 208. In one example, the gate dielectric 208 includes an oxide, although the invention is not so limited. The gate dielectric 208 is formed in a conformal layer over the fin 202, although the fin 202 is visible in FIG. 2A for illustration purposes. Further details of the arrangement of these elements are shown in X and Y cross sections detailed in FIGS. 2B and 2C.

In one example, a dummy gate 204 is formed from a sacrificial material, such as polysilicon. The dummy gate 204 is later removed, and replaced with a gate material having a different work function that is chosen to operate the transistor with more optimal electrical properties. Examples of final gate materials include, but are not limited to, tungsten, aluminum, or other metals. Replacement gates are discussed in more detail below, in reference to FIGS. 4A-B and 5A-B.

In FIG. 2B, an X-cut cross section 210 is shown. In FIG. 2C, a Y-cut cross section 220 is shown. The gate dielectric 208 is shown separating the dummy gate 204 from the fin 202. In FIG. 2C, multiple fins 202 are shown located over a semiconductor substrate 201. The gate dielectric 208 is shown as a conformal layer over the fins 202. Nitride layer 206 is also shown. In one example, the gate dielectric 208 is formed by oxidation of a surface portion of the fins 202, although the invention is not so limited. Other examples of gate dielectric 208 formation include deposition of an oxide or other dielectric over the fins 202.

A common thickness for gate dielectrics 208 is about 30-40 angstroms for devices that operate at less than about 1.8 volts. In some FinFET transistors, the gate dielectric needs to be thicker. For example, it is desirable to have gate dielectrics of 60 angstroms or more for some devices such as higher operating voltage devices. Using some manufacturing methods, it is necessary to remove a portion of gate dielectrics in regions adjacent to the channel in order to form source/drain regions to complete a transitory device. When devices have thicker gate dielectrics, a removal process such as etching can cause difficulties in manufacturing. In one example, due to the thicker cross section of the gate dielectric, an etching operation can cause unwanted undercut at the sides of the gate dielectric into the channel region. This may lead to unwanted short circuits between the gate and source/drain regions. It is desirable to form the needed thick gate dielectrics in the channel regions without the undesirable undercut issues and other undesirable dielectric removal, for example in adjacent shallow trench isolation regions.

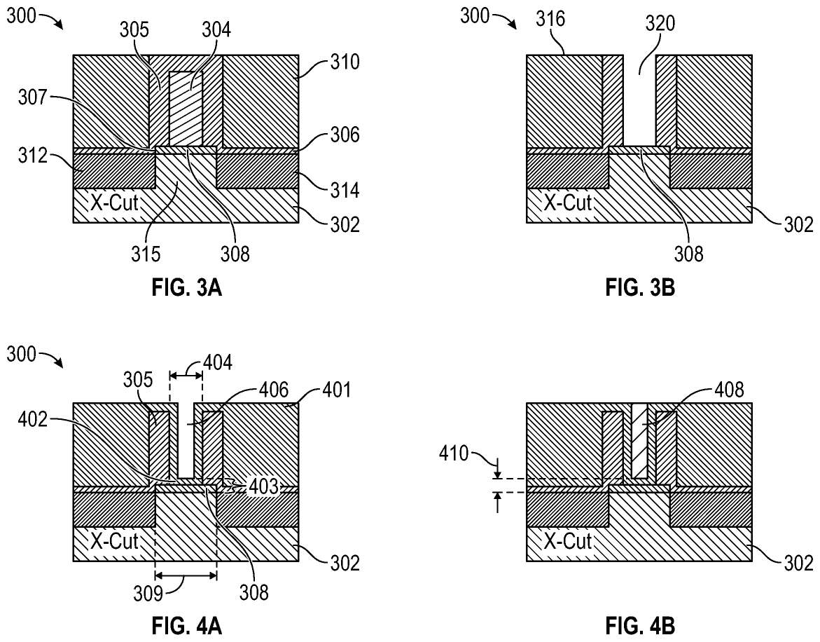

FIGS. 3A and 3B show selected stages of manufacturing a FinFET 300 that allow for a thicker gate dielectric without the negative effects such as undercut that were found in previous manufacturing methods. In one example, a thin gate dielectric is formed similar to the gate dielectric 208 shown in FIGS. 2A-2C. FIG. 3A shows a gate dielectric 308 formed over a channel 315

of a fin 302. In one example, the gate dielectric 308 serves as a first layer as described in more detail below. A dummy gate 304 is formed over the gate dielectric 308 from a sacrificial material, such as polysilicon.

A first source/drain region 312 and a second source/drain region 314 are shown formed in the fin 302 on either side of the channel 315. As shown in FIG. 3A, the gate dielectric 308 has been removed from adjacent to the source/drain regions 312, 314. Because the gate dielectric 308 is relatively thin at this stage of manufacture, undercut issues are reduced or eliminated due to the minimal thickness of the gate dielectric 308 at edges 307.

In selected examples, a nitride layer 306 is included over the source/drain regions 312, 314, and nitride spacers 305 are included on either side of the dummy gate 304. An insulator 310, such as an oxide, is further shown in FIG. 3A formed over the nitride layer 306 and at least partially encapsulating the dummy gate 304.

In FIG. 3B, a top surface of the insulator 310 is ground and planarized to expose the dummy gate 304. The dummy gate 304 is then removed to form an opening 320 that exposes the gate dielectric 308, or first layer of a final gate dielectric.

FIGS. 4A-4B show selected stages of manufacture to form a multi-layer gate dielectric according to one example. In FIG. 4A, the partially manufactured FinFET of FIG. 3B is further processed. In one example, the first layer 308 is less than 40 angstroms thick. In one example, the first layer 308 is less than 30 angstroms thick. A second layer 401 of dielectric material is formed over the first layer 308 of gate dielectric. A portion 402 of the second layer 401 of dielectric material, along with the first layer 308 of gate dielectric forms a multi-layer gate dielectric 403 that is a combination of the first layer 308 and the second layer 401. Although two layers are shown, the invention is not so limited. More than two layers are also within the scope of the invention.

In one example, the first layer 308 is the same chemistry as the second layer 401. One example of the same chemistry includes, but is not limited to, both layers 308, 401 being silicon oxide. In one example, the first layer 308 is a different chemistry from the second layer 401. One example of different chemistry includes the same elements, but in a different stoichiometry. For example, the first layer 308 may contain a greater percentage of oxygen than the second layer 401 even though both layers can be silicon oxide. In another example of different chemistry, the first layer 308 may include silicon oxide, and the second layer 401 may include a different metal oxide, such as hafnium oxide, or other oxides.

In one example, a microstructure of the first layer 308 and the second layer 401 are the same. The same or similar microstructure in both layers 308, 401 can result when both layers are formed using the same method, for example, vapor deposition. Other deposition techniques include, but are not limited to, sputtering, chemical deposition, atomic layer deposition, physical deposition, etc.

In one example, a microstructure of the first layer 308 and the second layer 401 are different. Different microstructures between layers 308, 401 can result when the layers 308, 401 are each formed using the different methods. For example, first layer 308 may be formed by oxidizing a portion of fin 302, while second layer 401 may be formed by vapor deposition or other methods.

In the Example of FIGS. 4A and 4B, because of the nitride spacers 305, the second layer portion 402 has a width 404 that is smaller than a width 309 of the first layer 308. The Figures further show the second layer 401 covering walls of the nitride spacers 305 to narrow the opening 320 from FIG. 3B to a narrower opening 406.

In FIG. 4B, a replacement gate 408 is formed in the opening 406 where the dummy gate 304 was removed. Because the opening 406 is within the nitride spacers 305 and the second layer 401, the replacement gate 408 has a width smaller than width 404. Examples of replacement gate 408 materials include, but are not limited to, tungsten, aluminum, or other high-K metal or conductor materials. As shown in FIG. 4B, the thickness 410 of multi-layer gate dielectric 403 is thicker than the first layer 308. In one example, the thickness 410 is greater than 60 angstroms, although the invention is not so limited.

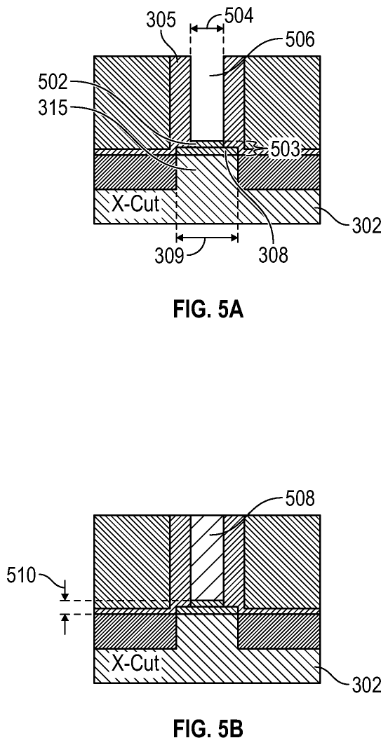

FIGS. 5A-5B show selected stages of manufacture to form a multi-layer gate dielectric according to another example. In FIG. 5A, the partially manufactured FinFET of FIG. 3B is further processed. In one example, the first layer 308 is less than 40 angstroms thick. In one example, the first layer 308 is less than 30 angstroms thick.

A second layer 501 of dielectric material is formed over the first layer 308 of gate dielectric. The second layer 502, along with the first layer 308 of gate dielectric forms a multi-layer gate dielectric 503 that is a combination of the first layer 308 and the second layer 502.

Similar to the example of FIGS. 4A-4B, in one example, the first layer 308 is the same chemistry as the second layer 502. One example of the same chemistry includes, but is not limited to, both layers 308, 502 being silicon oxide. In one example, the first layer 308 is a different chemistry from the second layer 502. One example of different chemistry includes the same elements, but in a different stoichiometry. For example, the first layer 308 may contain a greater percentage of oxygen than the second layer 502 even though both layers can be silicon oxide. In another example of different chemistry, the first layer 308 may include silicon oxide, and the second layer 502 may include a different metal oxide, such as hafnium oxide, or other oxides.

In one example, a microstructure of the first layer 308 and the second layer 502 are the same. The same or similar microstructure in both layers 308, 502 can result when both layers are formed using the same method, for example, vapor deposition. Other deposition techniques include, but are not limited to, sputtering, chemical deposition, atomic layer deposition, physical deposition, etc.

In one example, a microstructure of the first layer 308 and the second layer 502 are different. Different microstructures between layers 308, 502 can result when the layers 308, 502 are each formed using the different methods. For example, first layer 308 may be formed by oxidizing a portion of fin 302, while second layer 502 may be formed by rapid thermal oxidation or other methods. In one example, formation by rapid thermal oxidation only forms the second layer 502 on top of the first layer 308, and not on sidewalls of the nitride spacers 305. In the Example of FIGS. 5A and 5B, because of the nitride spacers 305, the second layer 502 has a width 504 that is smaller than a width 309 of the first layer 308.

In FIG. 5B, a replacement gate 508 is formed in an opening 506 where the dummy gate 304 was removed. Examples of replacement gate 508 materials include, but are not limited to, tungsten, aluminum, or other high-K metal or conductor materials. As shown in FIG. 5B, the thickness 510 of multi-layer gate dielectric 503 is thicker than the first layer 308. In one example, the thickness 510 is greater than 60 angstroms, although the invention is not so limited.

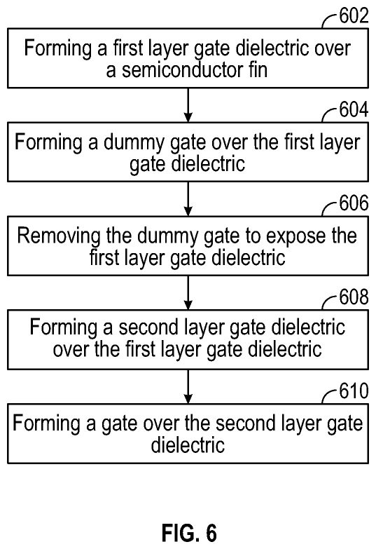

FIG. 6 shows an example flow diagram of a method of manufacture. In operation 602, a first layer gate dielectric is formed over a semiconductor fin. In operation 604, a dummy gate is formed over the first layer gate dielectric. In operation 606, the dummy gate is removed to expose the first layer gate dielectric. In operation 608, a second layer gate dielectric is formed over the first layer gate dielectric, and in operation 610, a gate is formed over the second layer gate dielectric.

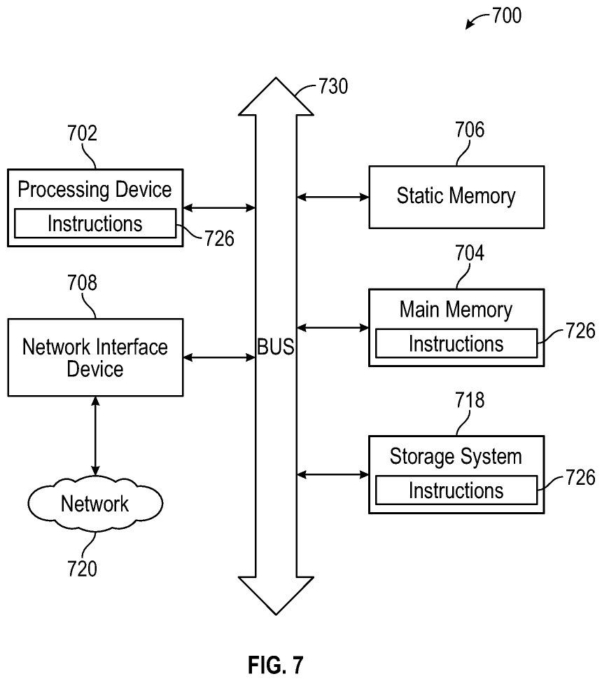

FIG. 7 illustrates a block diagram of an example machine (e.g., a host system) 700 which may include one or more transistors, memory devices and/or memory systems as described above. As discussed above, machine 700 may benefit from reliable thick gate dielectrics as described, facilitating improved performance of machine 700 (as for many such machines or systems, efficient reading and writing of memory can facilitate improved performance of a processor or other components that machine, as described further below.

In alternative embodiments, the machine 700 may operate as a standalone device or may be connected (e.g., networked) to other machines. In a networked deployment, the machine 700 may operate in the capacity of a server machine, a client machine, or both in server-client network environments. In an example, the machine 700 may act as a peer machine in peer-to-peer (P2P) (or other distributed) network environment. The machine 700 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 700 may include a processing device 702 (e.g., a hardware processor, a central processing unit (CPU), a graphics processing unit (GPU), a hardware processor core, or any combination thereof, etc.), a main memory 704 (e.g., read-only memory (ROM), dynamic random-access memory (DRAM) such as synchronous DRAM (SDRAM) or Rambus DRAM (RDRAM), etc.), a static memory 706 (e.g., static random-access memory (SRAM), etc.), and a storage system 718, some or all of which may communicate with each other via a communication interface (e.g., a bus) 730. In one example, the main memory 704 includes one or more memory devices as described in examples above.

The processing device 702 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 702 can also be one or more special-purpose processing devices such as an application specific integrated circuit (ASIC), a field programmable gate array (FPGA), a digital signal processor (DSP), network processor, or the like. The processing device 702 can be configured to execute instructions 726 for performing the operations and steps discussed herein. The computer system 700 can further include a network interface device 708 to communicate over a network 720.

The storage system 718 can include a machine-readable storage medium (also known as a computer-readable medium) on which is stored one or more sets of instructions 726 or software embodying any one or more of the methodologies or functions described herein. The instructions 726 can also reside, completely or at least partially, within the main memory 704 or within the processing device 702 during execution thereof by the computer system 700, the main memory 704 and the processing device 702 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 700 may further include a display unit, an alphanumeric input device (e.g., a keyboard), and a user interface (UI) navigation device (e.g., a mouse). In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 700 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 726 (e.g., software, programs, an operating system (OS), etc.) or other data are stored on the storage system 718 can be accessed by the main memory 704 for use by the processing device 702. The main memory 704 (e.g., DRAM) is typically fast, but volatile, and thus a different type of storage than the storage system 718 (e.g., an SSD), which is suitable for long-term storage, including while in an “off” condition. The instructions 726 or data in use by a user or the machine 700 are typically loaded in the main memory 704 for use by the processing device 702. When the main memory 704 is full, virtual space from the storage system 718 can be allocated to supplement the main memory 704; however, because the storage system 718 device is typically slower than the main memory 704, and write speeds are typically at least twice as slow as read speeds, use of virtual memory can greatly reduce user experience due to storage system latency (in contrast to the main memory 704, e.g., DRAM). Further, use of the storage system 718 for virtual memory can greatly reduce the usable lifespan of the storage system 718.

The instructions 724 may further be transmitted or received over a network 720 using a transmission medium via the network interface device 708 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.15 family of standards known as Wi-Fi®, IEEE 802.16 family of standards known as WiMax®), IEEE 802.15.4 family of standards, peer-to-peer (P2P) networks, among others. In an example, the network interface device 708 may include one or more physical jacks (e.g., Ethernet, coaxial, or phone jacks) or one or more antennas to connect to the network 720. In an example, the network interface device 708 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 700, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” (in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” is used herein to refer generally to any structure on which integrated circuits are formed, and also to such structures during various stages of integrated circuit fabrication. The term “substrate” is used to refer to either a wafer, or other structures which support or connect to other components, such as memory die or portions thereof. Thus, the term “substrate” embraces, for example, circuit or “PC” boards, interposers, and other organic or non-organic supporting structures (which in some cases may also contain active or passive components). The following detailed description is, therefore, not to be taken in a limiting sense, and the scope of the various embodiments is defined only by the appended claims, along with the full scope of equivalents to which such claims are entitled.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMS), read only memories (ROMs), and the like.

To better illustrate the method and apparatuses disclosed herein, a non-limiting list of embodiments is provided here:

Example 1 is a FinFET transistor. The transistor includes a semiconductor fin. The transistor also includes a first source/drain region and a second source/drain region separated by a channel within the fin. The transistor also includes a gate dielectric over the channel, wherein the gate dielectric includes a first layer having a first width, and a second layer over the first layer, wherein the second layer has a second width smaller than the first width, and a gate located over the gate dielectric.

In Example 2, the FinFET transistor of Example 1 optionally includes wherein the gate includes tungsten.

In Example 3, the FinFET transistor of any one of Examples 1-2 optionally includes wherein the first layer is the same chemistry as the second layer.

In Example 4, the FinFET transistor of any one of Examples 1-3 optionally includes wherein the first layer is the same microstructure as the second layer.

In Example 5, the FinFET transistor of any one of Examples 1-4 optionally includes wherein the first layer is a different microstructure from the second layer.

In Example 6, the FinFET transistor of any one of Examples 1-5 optionally further includes nitride spacers on either side of the gate.

In Example 7, the FinFET transistor of any one of Examples 1-6 optionally further includes both nitride and oxide layers on either side of the gate.

In Example 8, the FinFET transistor of any one of Examples 1-7 optionally includes wherein the gate has a width smaller than the second width.

Example 9 is a memory device. The memory device includes an array of memory cells and peripheral circuitry adjacent to the array of memory cells. The peripheral circuitry includes one or more FinFET transistors, including a semiconductor fin, a first source/drain region and a second source/drain region separated by a channel within the fin, a gate dielectric over the channel, wherein the gate dielectric includes a first layer having a first width, and a second layer over the first layer, wherein the second layer has a second width smaller than the first width, and a gate located over the gate dielectric.

In Example 10, the memory device of Example 9 optionally includes wherein a combined thickness of first layer and second layer is greater than 60 Angstroms.

In Example 11, the memory device of any one of Examples 9-10 optionally includes wherein the FinFET is configured to operate at a voltage higher than 1.8 volts.

In Example 12, the memory device of any one of Examples 9-11 optionally includes wherein the gate includes tungsten.

In Example 13, the memory device of any one of Examples 9-12 optionally includes wherein the first layer is the same chemistry as the second layer.

In Example 14, the memory device of any one of Examples 9-13 optionally includes wherein the first layer is the same microstructure as the second layer.

In Example 15, the memory device of any one of Examples 9-14 optionally includes wherein the first layer is a different microstructure from the second layer.

Example 16 is a method. The method includes forming a first layer gate dielectric over a semiconductor fin, forming a dummy gate over the first layer gate dielectric, removing the dummy gate to expose the first layer gate dielectric, forming a second layer gate dielectric over the first layer gate dielectric, and forming a gate over the second layer gate dielectric.

In Example 17, the method of Example 16 optionally includes wherein forming the first layer gate dielectric includes atomic layer deposition.

In Example 18, the method of any one of Examples 16-17 optionally includes wherein forming the second layer gate dielectric includes atomic layer deposition.

In Example 19, the method of any one of Examples 16-18 optionally includes wherein forming the second layer gate dielectric includes rapid thermal oxidation.

In Example 20, the method of any one of Examples 16-19 optionally includes wherein forming the dummy gate includes forming a polysilicon dummy gate with nitride spacers on either side.

In Example 21, the method of any one of Examples 16-20 optionally includes wherein forming the second layer gate dielectric includes forming to a width within the nitride spacers.

In Example 22, the method of any one of Examples 16-21 optionally includes wherein forming the gate over the second layer gate dielectric include forming to a width of the second layer gate dielectric.

In Example 23, the method of any one of Examples 16-22 optionally includes wherein forming the gate over the second layer gate dielectric include forming to a width smaller than the second layer gate dielectric.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A FinFET transistor, comprising:
a semiconductor fin;
a first source/drain region and a second source/drain region separated by a channel within the fin;
a gate dielectric over the channel, wherein the gate dielectric includes a first layer having a first width, and a second layer over the first layer, wherein the second layer has a second width smaller than the first width; and
a gate located over the gate dielectric.

2. The FinFET transistor of claim 1, wherein the gate includes tungsten.

3. The FinFET transistor of claim 1, wherein the first layer is the same chemistry as the second layer.

4. The FinFET transistor of claim 1, wherein the first layer is the same microstructure as the second layer.

5. The FinFET transistor of claim 1, wherein the first layer is a different microstructure from the second layer.

6. The FinFET transistor of claim 1, further including nitride spacers on either side of the gate.

7. The FinFET transistor of claim 1, further including both nitride and oxide layers on either side of the gate.

8. The FinFET transistor of claim 1, wherein the gate has a width smaller than the second width.

9. A memory device, comprising:
an array of memory cells;
peripheral circuitry adjacent to the array of memory cells, the peripheral circuitry including one or more FinFET transistors, including:
a semiconductor fin;
a first source/drain region and a second source/drain region separated by a channel within the fin;
a gate dielectric over the channel, wherein the gate dielectric includes a first layer having a first width, and a second layer over the first layer, wherein the second layer has a second width smaller than the first width; and
a gate located over the gate dielectric.

10. The memory device of claim 9, wherein a combined thickness of first layer and second layer is greater than 60 Angstroms.

11. The memory device of claim 9, wherein the FinFET is configured to operate at a voltage higher than 1.8 volts.

12. The memory device of claim 9, wherein the gate includes tungsten.

13. The memory device of claim 9, wherein the first layer is the same chemistry as the second layer.

14. The memory device of claim 9, wherein the first layer is the same microstructure as the second layer.

15. The memory device of claim 9, wherein the first layer is a different microstructure from the second layer.

16. A method, comprising:
forming a first layer gate dielectric over a semiconductor fin;
forming a dummy gate over the first layer gate dielectric;
removing the dummy gate to expose the first layer gate dielectric;
forming a second layer gate dielectric over the first layer gate dielectric; and
forming a gate over the second layer gate dielectric.

17. The method of claim 16, wherein forming the first layer gate dielectric includes atomic layer deposition.

18. The method of claim 16, wherein forming the second layer gate dielectric includes atomic layer deposition.

19. The method of claim 16, wherein forming the second layer gate dielectric includes rapid thermal oxidation.

20. The method of claim 16, wherein forming the dummy gate includes forming a polysilicon dummy gate with nitride spacers on either side.

21. The method of claim 16, wherein forming the second layer gate dielectric includes forming to a width within the nitride spacers.

22. The method of claim 21, wherein forming the gate over the second layer gate dielectric include forming to a width of the second layer gate dielectric.

23. The method of claim 16, wherein forming the gate over the second layer gate dielectric include forming to a width smaller than the second layer gate dielectric.
